(19) United States
(12) Patent Application Publication
(10) Pub. No.: US 2012/0229195 A1
(43) Pub. Date: Sep. 13, 2012

(54) CAPACITANCE TYPE INPUT DEVICE

(76) Inventor: Hiroshi Shigetaka, Miyagi-ken (JP)

(21) Appl. No.: 13/360,273

(22) Filed: Jan. 27, 2012

(30) Foreign Application Priority Data
Mar. 10, 2011 (JP) 2011-052554

(51) Int. Cl. H03K 17/96

(52) U.S. Cl. 327/517

(57) ABSTRACT

A capacitance type input device includes: a film base material; a driving electrode patterned at a sensor side of the film base material; and a detection electrode patterned to output capacitance between the driving electrode and the detection electrode, opposite to the driving electrode through a sensor side insulating layer, in which reference capacitor portions having reference capacitance for capacitance between the driving electrode and the detection electrode are patterned at the side of a circuit portion opposite to the sensor portion of the film base material. The reference capacitor portion includes a first conductive layer conductively connected with the detection electrode and a second conductive layer opposite to the first conductive layer through a circuit side insulating layer.

### CLAIM OF PRIORITY

This application claims benefit of Japanese Patent Application No. 2011-052554 filed on Mar. 10, 2011, which is hereby incorporated by reference in its entirety.

### BACKGROUND

1. Field of the Disclosure

The present disclosure relates to a capacitance type input device that detects the approach of a finger from a change in capacitance between a driving electrode and a detection electrode, particularly, a configuration including a reference capacitor portion at a circuit portion.

2. Description of the Related Art

A capacitance type input device, as described in Japanese Unexamined Patent Application Publication No. 9-54650, Japanese Unexamined Patent Application Publication No. 2003-271311 and U.S. RE 40,867E, includes a sensor portion having a base and an electrode pattern and a circuit portion conductively connected with the electrode pattern of the sensor portion.

Although the sensor portion and the circuit portion are separately provided in Japanese Unexamined Patent Application Publication No. 9-54650 and Japanese Unexamined Patent Application Publication No. 2003-271311, there has been known a configuration in which a sensor portion and a circuit portion are provided on a common film base material, as in U.S. RE 40,867E.

In the related art, in the configuration in which the electrode pattern included in a sensor portion is formed on a film base material, capacitance between electrode patterns is dispersed in accordance with the environment by a change in dielectric constant of the film base material or an insulating layer due to an environmental change, which results in a problem in that the accuracy of positional detection decreases.

### SUMMARY

A capacitance type input device includes: a film base material; a driving electrode patterned at a sensor portion side of the film base material; and a detection electrode patterned to detect capacitance between the driving electrode and the detection electrode, opposite to the driving electrode through a sensor side insulating layer, in which the reference capacitor portion where a first conductive layer and a second conductive layer oppose each other through a circuit side insulating layer are patterned is disposed at a circuit portion side opposite to the sensor portion of the film base material, and a reference capacitor for capacitance between the driving electrode and the detection electrode is formed between the first conductive layer and the second conductive layer.

### BRIEF DESCRIPTION OF THE DRAWINGS

FIG. 1 is a plan view of a capacitance type input device according to an embodiment.

FIG. 2 is a rear view of a capacitance type input device according to the embodiment.

FIG. 3 is a partial enlarged longitudinal cross-sectional view of the capacitance type input device, taken along the line A-A of FIG. 1 and seen in the direction of the arrow.

FIG. 4 is a partial enlarged longitudinal cross-sectional view of the capacitance type input device, taken along the line B-B of FIG. 1 and seen in the direction of the arrow.

FIG. 5 is a partial enlarged longitudinal cross-sectional view of a reference capacitor portion according to a first embodiment.

FIG. 6A is a partial enlarged longitudinal cross-sectional view of a reference capacitor portion according to a second embodiment and FIG. 6B is a perspective view of the reference capacitor portion according to the second embodiment.

FIG. 7 is a schematic view of a pointing device using the capacitance type input device according to another embodiment.

FIG. 8 is a schematic view of a pointing device using the capacitance type input device according to still another embodiment.

FIG. 9 is a schematic view of a pointing device using the capacitance type input device according to still another embodiment.

FIG. 10 is a schematic view of a pointing device using the capacitance type input device according to still another embodiment.

### DESCRIPTION OF THE EXEMPLARY EMBODIMENTS

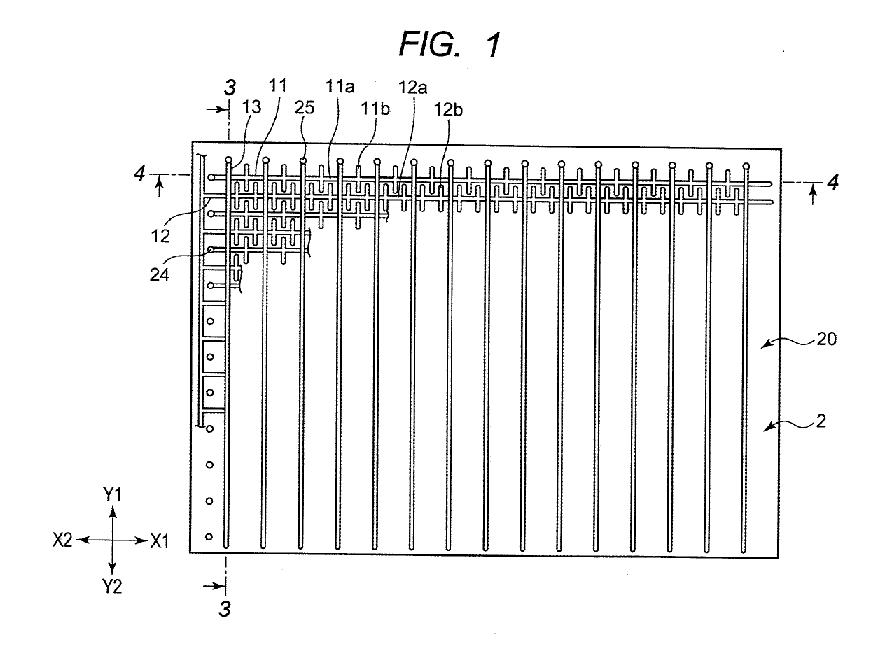

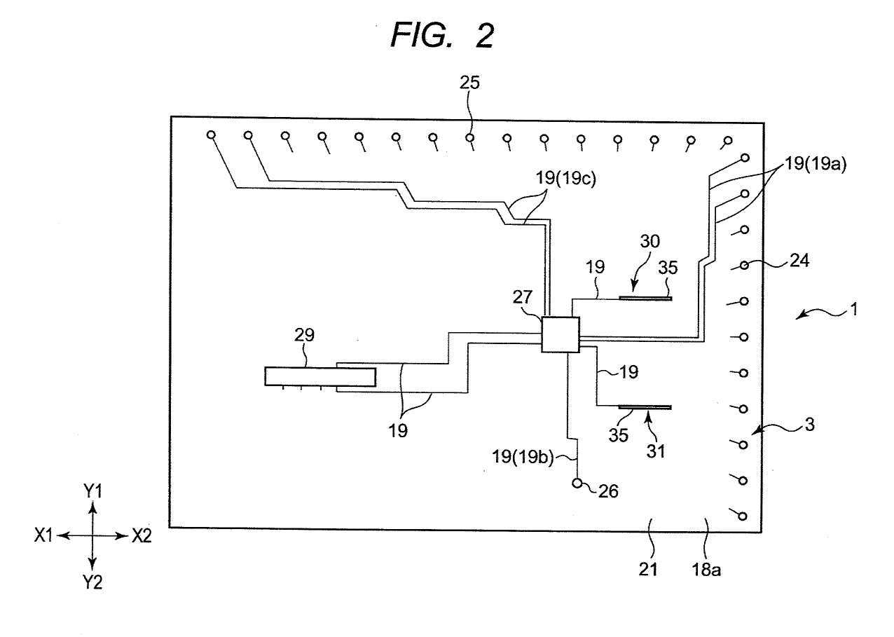

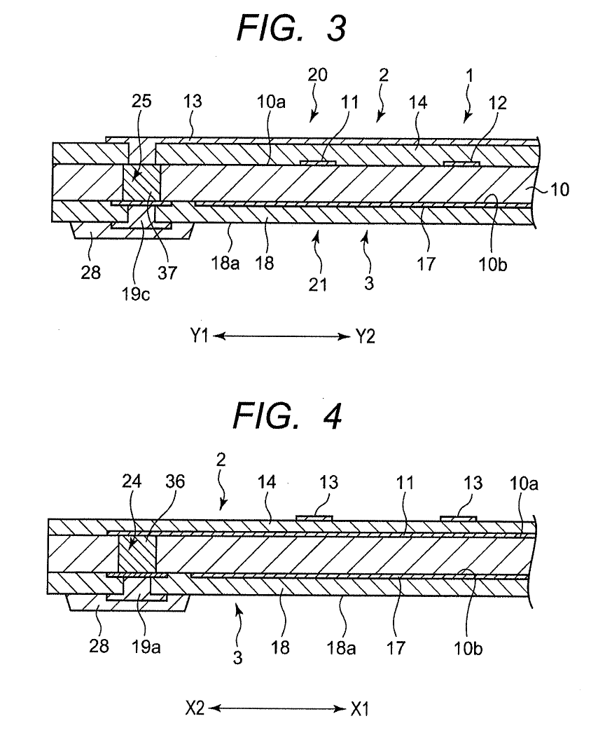

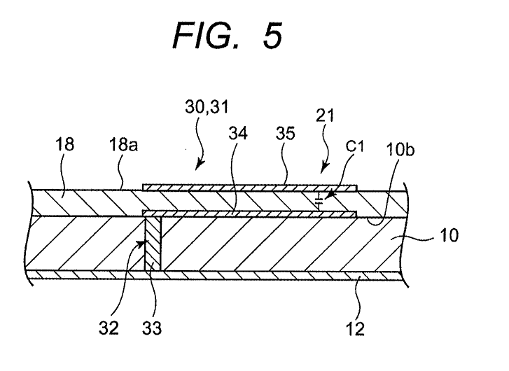

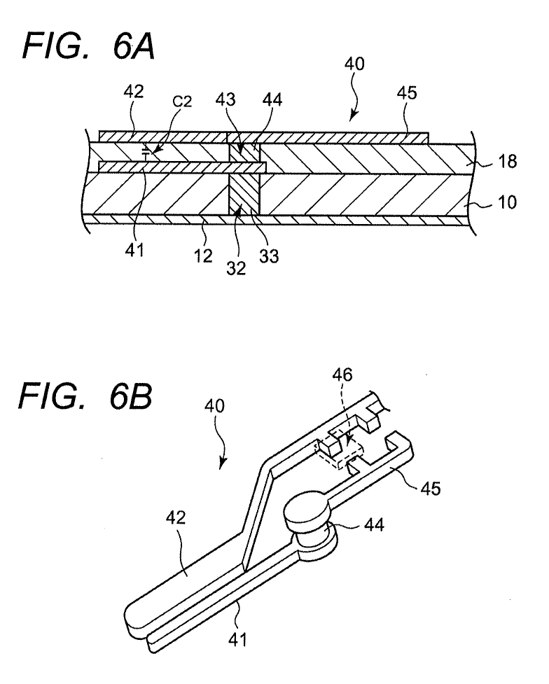

FIG. 1 is a plan view of a capacitance type input device 1 according to an embodiment, FIG. 2 is a rear view of the capacitance type input device, FIG. 3 is a partial enlarged longitudinal cross-sectional view taken along the line A-A of FIG. 1 and seen in the direction of the arrow, FIG. 4 is a partial enlarged longitudinal cross-sectional view taken along the line B-B of FIG. 1 and seen in the direction of the arrow, FIG. 5 is a partial enlarged longitudinal cross-sectional view of a reference capacitor portion according to a first embodiment, FIG. 6A is a partial enlarged longitudinal cross-sectional view of a reference capacitor portion according to a second embodiment, and FIG. 6B is a perspective view of the reference capacitor portion according to the second embodiment. However, in FIGS. 5 and 6, the rear side (circuit portion side) of the capacitance type input device is arranged upward.

As shown in the cross-sectional views of FIGS. 3 and 4, the capacitance type input device 1 has a front side 2 and rear side 3. FIG. 1 shows the capacitance type input device 1 seen from the front side 2 and FIG. 2 shows the capacitance type input device 1 seen from the rear side 3.

As shown in FIG. 1, X-driving electrode (first driving electrode) 13, a Y-driving electrode (second driving electrode) 11, and a detection electrode 12 are disposed throughout nearly all regions of the front side 2. Further, the reference numeral 13 is given to one X-driving electrode in FIG. 1. Further, only some portions of the Y-driving electrode and the detection electrode are shown in FIG. 1 and the reference numerals 11 and 12 are given to one Y-driving electrode and one detection electrode, respectively.

The electrodes 11, 12, and 13 are patterned by printing.

As shown in FIGS. 3 and 4, the capacitance type input device 1 a flexible film base material 10 formed of a resin film or a resin sheet. The synthetic resin of the film base material 10 is, for example, PET (polyethylene terephthalate).

The front side 2 of the film base material 10 forms a sensor portion 20, and a plurality of Y-driving electrodes 11 and a plurality of detection electrodes 12 shown in FIG. 1 are formed, directly or via an insulating layer, on the surface 10a of the film base material 10.

A sensor side insulating layer 14 is disposed on the surfaces of the Y-driving electrode 11 and the detection electrode 12 and the X-driving electrode 13 is formed on the sensor side insulating layer 14. The surface of the X-driving electrode 13 is covered with a surface insulating layer, which is not shown.

As shown in FIG. 1, the Y-driving electrode 11 has an electrode main body portion 11a extending straight in the X1-X2 direction. The plurality of Y-driving electrodes 11 is formed such that the electrode main body portions 11a extend in parallel with a uniform gap in the Y1-Y2 direction. The detection electrode 12 has an electrode main body portion 12a extending straight in the X1-X2 direction and the plurality of detection electrodes 12 are formed such that the electrode main body portions 12a extend in parallel with a uniform gap in the Y1-Y2 direction. The electrode main body portions 11a of the Y-driving electrodes 11 and the electrode main body portions 12a of the detection electrodes 12 are alternately arranged in the Y1-Y2 direction while the electrode main body portions 11a and the electrode main body portions 12a are parallel to each other.

As shown in FIG. 1, the X-driving electrodes 13 extend straight in the Y1-Y2 direction, in parallel with each other with a uniform gap in the X1-X2 direction.

As shown in FIG. 1, the Y-driving electrode 11 has a branch electrode portion 11b. A plurality of branch electrode portions 11b is formed with a gap in the X1-X2 direction and each is conductively connected with the electrode main body portion 11a and protrudes a small amount in the Y1 direction and the Y2 direction from the electrode main body portion 11a. The detection electrode 12 also has a branch electrode portion 12b. A plurality of branch electrodes 12b is disposed with a gap in the X1-X2 direction. Each of the branch electrodes 12b is conductively connected with the electrode main body portion 12a and protrudes a small amount in the Y1 direction and the Y2 direction from the electrode main body portion 12a.

As shown in FIG. 1, the X-driving electrodes 13 cross the electrode main body portions 11a of the Y-driving electrodes 11 and the electrode main body portions 12a of the detection electrode 12 above them. Further, as the branch electrode 12b is provided to the detection electrode 12, coupling capacitance of the detection electrode 12 and the X-driving electrode 13 can be increased at the intersection of the electrode main body portion 11a of the detection electrode 12 and the X-driving electrode 13 while coupling capacitance of the detection electrode 12 and the X-driving electrode 13 is adjusted without large variations throughout an operation surface.

Although a branch electrode is not provided to the X-driving electrode 13 in the embodiment shown in FIG. 1, a branch electrode may be provided to the X-driving electrode 13.

The electrode main body portion 11a of the Y-driving electrode 11 and the electrode main body portion 12a of the detection electrode 12 are opposite in parallel to each other while the branch electrode 11b of the Y-driving electrode 11 and a pair of branch electrodes 12b of the detection electrode 12 are arranged opposite to each other in the X1-X2 direction. As the branch electrode 11b and the branch electrode 12b are provided, coupling capacitance of the Y-driving electrode 11 and the detection electrode 12 can be increased while the coupling electrode of the Y-driving electrode 11 and the detection electrode 12 is adjusted without large variations throughout the operation surface.

As shown in FIG. 2, the rear side 3 of the film base material 10 forms the circuit portion 21 and, as shown in FIGS. 3 and 4, a ground layer (shield layer) 17 made of a conductive material is formed on the rear surface 10b of the film base material 10. The ground layer 17 is formed to cover almost the entire area of the operation surface from the rear side.

As shown in FIGS. 3 and 4, the rear surface of the ground layer 17 is covered with a circuit side insulating layer 18. A circuit wiring layer 19 is formed on the rear surface 18a of the circuit side insulating layer 18, as shown in FIGS. 2, 3, and 4. Further, only a portion of the circuit wiring layer 19 is shown in FIG. 2.

As shown in FIG. 2, the circuit wiring layer 19 includes Y-wiring layer 19a, a detecting wiring layer 19b, and an X-wiring layer 19c.

As shown in FIG. 1, through-holes 24 and 25 are formed along the edge portion of the operation surface. Further, the reference numerals 24 and 25 are given to one through-hole 24 and 25, respectively, in FIGS. 1 and 2. As shown in FIGS. 3 and 4, the through-holes 24 and 25 are formed through the film base material 10 and filled with conductive layers 36 and 37, respectively. Further, the plurality of Y-driving electrodes 11 and the Y-wiring layer 19a are separately and conductively connected through the conductive layer 36 in the through-hole 24. Similarly, the plurality of X-driving electrodes 13 and the X-wiring layer 19c are separately and conductively connected through the conductive layer 37 in the through-hole 25.

Further, one through-hole 26 is provided for the detection electrode 12, as shown in FIG. 2, the through-hole 26 is also formed through the film base material 10 and filled with a conductive layer. Further, the detection electrodes 12 are collected in one unit one detecting wire layer 19b conductively connected with the detection electrode 12 through the through-hole 26 are formed at the circuit portion 21.

As shown in FIG. 2, an IC package 27 that is an electronic element is mounted on the rear surface 18a of the circuit side insulating layer 18 in the circuit portion 21 and the circuit wiring layer 19 is conductively connected to the circuit in the IC package 27. A driving circuit or a detecting circuit is included in the IC package 27. Further, the circuit wiring layer 19 extends from the IC package 27 and connected to a connector portion 29.

Further, as shown in FIGS. 3 and 4, the circuit wiring layer 19 is covered with the wiring insulating layer 28. However, the wiring insulating layer 28 is not formed at the portion of the mounting land portion (not shown) and the mounting land portion is exposed.

Although the materials of the layers are not specifically limited in the embodiment, they can be formed by printing, and for example, the electrodes 11, 12, and 13, the circuit wiring layer 19, and the conductive layer of a reference capacitor portion (described below) are formed in a structure of a conductive layer containing silver, a conductive layer containing carbon, or a structure formed by stacking the layers. Further, the insulating layers 14, 18, and 28 are, for example, formed of registers.

Voltage with a pulse shape is applied to the Y-driving electrode 11 at uniform time intervals through the Y-wiring layer 19a by the driving circuit in the IC package 27. The voltage with a pulse shape is sequentially applied to the plurality of Y-driving electrodes 11. Further, voltage with a pulse shape is applied to the X-driving electrode 13 at uniform time intervals through the X-wiring layer 19c by the driving circuit and the voltage with a pulse shape is also sequentially applied to the plurality of X-driving electrodes 13. However, voltage is applied to the Y-driving electrode 11 and the X-driving electrode 13 at different times.

A capacitance is formed between the Y-driving electrode 11 and the detection electrode 12. When voltage with a pulse shape is applied to some of the Y-driving electrodes 11, temporary current flows to the detection electrodes 12 adjacent to the Y-driving electrodes 11 where the voltage is applied, simultaneously with the initial rise of the voltage. When a person's finger (operating body) substantially contacts the grounding potential comes in contact with the operation surface of the sensor portion 20 and the finger approaches some of the Y-driving electrode 11, a capacitance is formed between the finger and the Y-driving electrodes 11 while capacitance is formed between the finger and the detection electrode 12, such that the capacitance between the detection electrode 12 and the Y-driving electrodes 11 where the finger approaches changes. The amount of current flowing to the detection electrode 12 changes with the change in the capacitance, such that a change occurs between the amount of current flowing to the detection electrode 12 when voltage is applied to the Y-driving electrode 11 where the finger approaches and the amount of current flowing to the detection electrode 12 when voltage is applied to the Y-driving electrode 11 where the finger is not approaching.

Two reference capacitor portions 30 and 31 are formed in the circuit portion 21 in the embodiment. Reference capacitance is set in the reference capacitor portions 30 and 31.

The configuration of the reference capacitor portions 30 and 31 is described here. As shown in FIG. 5 (the side of the circuit portion 21 shown in FIG. 2 is at the upper side), a through-hole 32 is formed in the film base material 10, and the conductive layer 33 filled in the through-hole 32 and the detection electrode 12 are conductively connected.

As shown in FIG. 5, a first conductive layer 34 is patterned by printing on the same forming surface (rear surface 10b of the film base material 10) as the ground layer 17, at the side of the circuit portion 21. As shown in FIG. 5, the detection electrode 12 and the first conductive layer 34 are conductively connected through the conductive layer 33.

Further, as shown in FIG. 5, a second conductive layer 35 is formed on the same forming surface (the rear surface 18a of the circuit side insulating layer 18) as the circuit wiring layer 19. The second conductive layer 35 is opposite to the first conductive layer 34 through the circuit side insulating layer 18 while a reference capacitance C1 is formed between the first conductive layer 34 and the second conductive layer 35. As shown in FIG. 2, the second conductive layer 35 is patterned by printing and connected to the IC package 27 through the circuit wiring layer 19. Further, the second conductive layer 35 and the circuit wiring layer 19 may be integrally formed.

For example, reference numeral ‘30’ in FIG. 2 indicates a first reference capacitor portion 30 having the reference capacitance C1 for the capacitance between the X-driving electrode 13 and the detection electrode 12 and reference numeral ‘31’ indicates a second reference capacitor portion 31 having the reference capacitance C1 for the capacitance between the Y-driving electrode 11 and the detection electrode 12.

As described above, the amount of current flowing to the detection electrode 12 is detected by sequentially applying voltage to the Y-driving electrodes 11. Further, voltage with a pulse shape is also applied to the second conductive layer 35 of the second reference capacitor portion 31. Further, the reference current value is detected by the detection electrode 12 and the detecting wiring layer 19b on the basis of the reference capacitance C1 of the second reference capacitor portion 31.

Current values based on the reference current value and the capacitance between the Y-driving electrode 11 and the detection electrode 12 are compared in the detecting circuit of the IC package 27. When a finger does not come in contact with the operation surface, the difference between the current values acquired by applying voltage to the Y-driving electrodes and the reference current value is in a predetermined range, such that it possible to determine that the finger is not approaching. Meanwhile, when the finger approach the operation surface, the current value acquired when voltage is applied to the Y-driving electrode 11 close to the finger changes in comparison to the current value when the finger is not approaching, such that it is possible to estimate the position of the portion where the finger approaches on the Y coordinate from how much the current values acquired when voltage is applied to the Y-driving electrodes 11 as compared with the reference current value. Similarly, the amount of current flowing to the detection electrode 12 is detected by sequentially applying voltage with a pulse shape to the X-driving electrodes 13 and the second conductive layer 35 of the first reference capacitor portion 30. Further, it is possible to estimate the position of the portion where the finger approaches in the X coordinate from how much the current values acquired when voltage is applied to the X-driving electrodes 13 as compared with the reference current value.

Further, according to the capacitance type input device including the reference capacitor portion having the reference capacitance of the embodiment, for example, it is possible to detect a state where a finger comes in contact with the entire operation surface, for example.

A feature of the capacitance type input device 1 according to the embodiment is that the first conductive layer 34 and the second conductive layer 35 oppose each other through the circuit side insulating layer 18 are patterned by printing at the side of the circuit portion 21 and the reference capacitor portions 30 and 31 having the reference capacitance are disposed.

Therefore, it is possible to provide both the reference capacitor portions 30 and 31 disposed on the rear side 3 of the film base material 10 and the sensor portion 20 disposed on the front side 2 of the film base material 10 with dependence on a dielectric constant of the film base material 10 or the insulating layers 14 and 18. As described above, the film base material 10 is a PET film or the like and easily changes in dielectric constant due to an environmental change. Further, the insulating layers 14 and 18 are also formed of resistors or the like and easily changed in dielectric constant by an environmental change. Therefore, although the capacitance between the patterned electrodes of the sensor portion 20 is easily changed by a change in dielectric constant of the film base material 10 or the insulating layers 14 and 18 due to an environmental change, by patterning reference capacitor portions 30 and 31 in the embodiment, the reference capacitance of the reference capacitor portions 30 and 31 can be changed on the basis of a change in dielectric constant of the film substrate 10 or the insulating layers 14 and 18, as the side of the sensor portion 20, such that it is possible to reduce detection errors even with respect to temperature and humidity drift of the capacitance between the electrodes and it is possible to acquire excellent accuracy in position detection.

Further, in the configuration where the reference capacitor portion having the reference capacitance is implemented by a condenser chip, as in the sensor portion, the reference capacitor portion cannot be provided with dependence on a dielectric constant of the film base material 10 or the insulating layers 14 and 18, such that it is difficult to appropriately improve the accuracy of position detection.

In the embodiment, since the reference capacitor portions 30 and 31 are patterned, as compared with a configuration where a condenser chip is provided, it is possible to appropriately improve the accuracy of position detection and promote a reduction in the number or parts and the thickness. Further, in the embodiment, it is possible to form the conductive layers on the front side 2 and the rear side 3 of the film base material 10 by printing, it is possible to form the first conductive layer 34 in the same process as the ground layer 17, in forming of the reference capacitor portions 30 and 31, and it is possible to form the second conductive layer 35 in the same process as the circuit wiring layer 19. Therefore, it is possible to reduce the manufacturing cost, as compared with the configuration where a condenser chip is provided as the reference capacitor portion, without increasing the manufacturing processes for forming the reference capacitor portions 30 and 31.

In the embodiment, as shown in FIG. 5, the reference capacitor portions 30 and 31 have the first conductive layer 34 conductively connected with the detection electrode 12 through the conductive layer 33 in the through-hole 32 of the film base material 10 and the second conductive layer 35 opposite to the first conductive layer 34 through the circuit side insulating layer 18, such that it is possible to simplify the wiring pattern (electric circuit) from the side of the sensor portion 20 to the IC package 27 of the side of the circuit 21 and it is also possible to form the reference capacitor portions 30 and 31 with a simple structure.

Further, in the embodiment, as shown in FIGS. 2 and 5, it is preferable to extend straight the first conductive layer 34 and the second conductive layer 35 at a predetermined length according to reference capacitance C1. It is possible to form the reference capacitor portions 30 and 31 having a desired reference capacitance C1 with a simple structure.

Further, in the embodiment, it is preferable to form the sensor side insulating layer 14 disposed at the side of the sensor portion 20 and the circuit side insulating layer 18 disposed at the side of the circuit 21 in the same layer configuration. The “same layer configuration means a configuration implemented by the same material with substantially the same thickness. Therefore, it is possible to provide the sensor portion 20 and the reference capacitor portions 30 and 31 with the same dependence on a dielectric constant to the insulating layer, such that it is possible to more effectively improve the accuracy of position detection.

FIG. 6 shows a second embodiment of a reference capacitor portion 40. As shown in FIGS. 6A and 6B, the reference capacitor portion 40 includes a first conductive layer 41 and a second conductive layer 42 and the first conductive layer 41 is conductively connected with the detection electrode 12 through the conductive layer 33. The conductive layer 33 is formed in a through-hole 32 formed in the film base material 10.

As shown in FIG. 6A, the first conductive layer 41 and the second conductive layer 42 are opposite to each other through the circuit side insulating layer 18 and a reference capacitance C2 is formed between the first conductive layer 41 and the second conductive layer 42.

Further, in the reference capacitor portion 40 shown in FIG. 6, the through-hole 43 is formed in the circuit side insulating layer 18 and a conductive layer 44 is embedded in the through-hole 43. Further, the first conductive layer 41 and a third conductive layer 45 are conductively connected through the conductive layer 44.

As shown in FIG. 6B, the second conductive layer 42 extends to a position opposite to the third conductive layer 45 when seen from above, and a condenser chip 46 for fine adjustment, which is opposite to the capacitance C2, is disposed between the second conductive layer 42 and the third conductive layer 45. Further, the capacitance of the condenser chip 46 for fine adjustment is sufficiently smaller than the reference capacitance C2, for example, 1/10 of the reference capacitance C2.

The condenser chip 46 for fine adjustment is provided for fine adjustment when a problem, such as the reference capacitance C2 being dispersed, when the first conductive layer 41 and the second conductive layer 42 of the reference capacitor portion 40 are printed, but it is possible to arbitrarily determine whether to dispose the condenser chip 46 for fine adjustment.

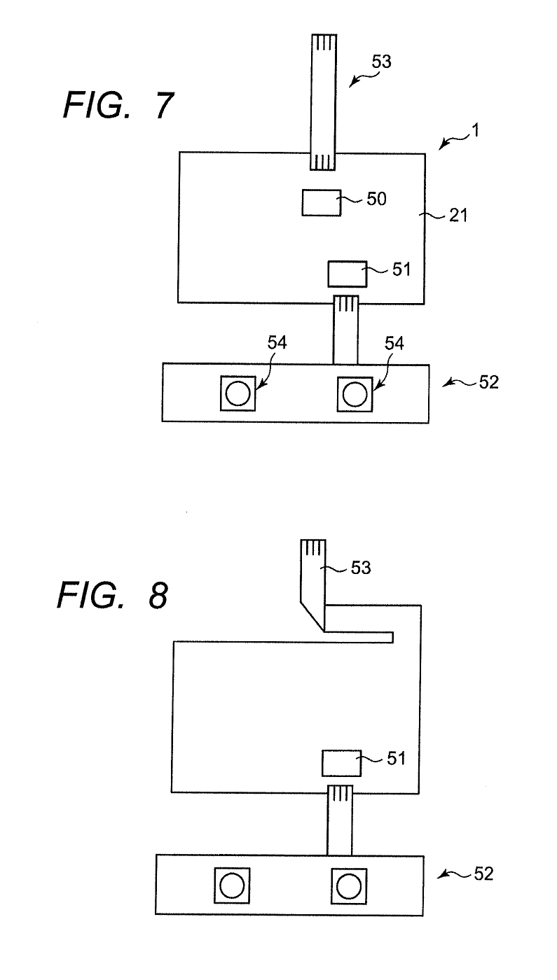

The capacitance type input device according to the embodiment can be used as a pointing device mounted in a notebook or the like, and for example, as shown in FIG. 7, two connector portions 50 and 51 are attached to the circuit portion 21 on the rear side of the capacitance type input device 1. Further, a flexible flat cable 53 is connected to one connector portion 50 and a flexible print substrate 52 having switch portions 54 and 54 and a metal plate is connected to the other connector portion 51.

Further, as shown in FIG. 8, it is possible to integrally form flexible flat cable 53 shown in FIG. 7 by extending the film base material of the capacitance type input device 1 according to the embodiment, as shown in FIG. 8. Therefore, it is possible to reduce the connector portion 50 in FIG. 8 in comparison to FIG. 7 and it is possible to reduce the number of parts.

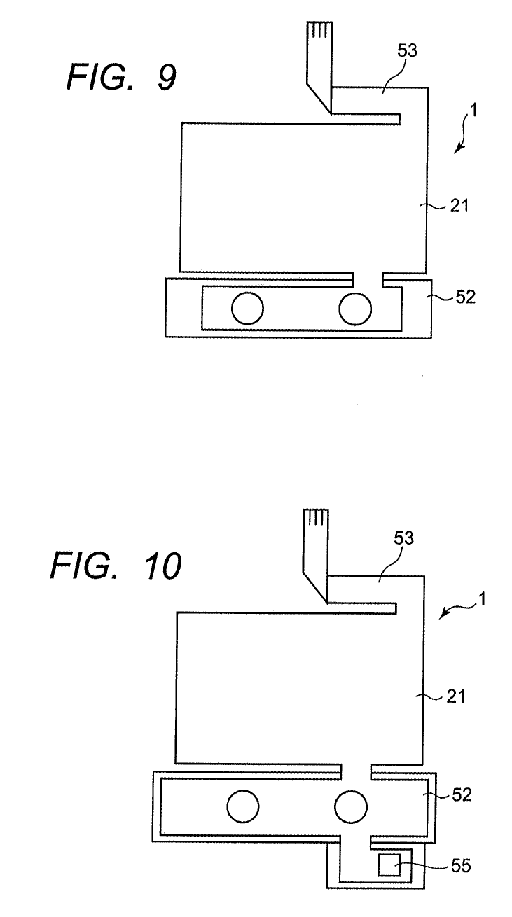

Further, as shown in FIG. 9, since it is possible to integrally form the flexible print substrate 52 shown in FIG. 7 by extending the film base material for the flexible flat cable 53 and also for the flexible print substrate 52, it is possible to remove the connector portions 50 and 51 shown in FIG. 7.

Further, in FIG. 10, a hole IC 55 is attached to further extending the film base material.

It should be understood by those skilled in the art that various modifications, combinations, sub-combinations and alterations may occur depending on design requirements and other factors insofar as they are within the scope of the appended claims of the equivalents thereof.

What is claimed is:

1. A capacitance type input device comprising:
a film base material;
a driving electrode patterned at a sensor side portion of the film base material; and
a detection electrode patterned to detect capacitance between the driving electrode and the detection electrode, opposite to the driving electrode through a sensor side insulating layer,
wherein the reference capacitor portion where a first conductive layer and a second conductive layer oppose each other through a circuit side insulating layer are patterned is disposed at a circuit portion side opposite to the sensor portion of the film base material, and a reference capacitance for capacitance between the driving electrode and the detection electrode is formed between the first conductive layer and the second conductive layer.

2. The capacitance type input device according to claim 1,
wherein the first conductive layer is conductively connected with the detection electrode through the film base material.

3. The capacitance type input device according to claim 1,
wherein the first conductive layer and the second conductive layer extend straight at a predetermined length in accordance with the reference capacitance.

4. The capacitance type input device according to claim 1,
wherein a ground layer, a circuit side insulating layer, and a circuit wiring layer are sequentially stacked in order from the film base material, the first conductive layer is formed by the same process as the ground layer, and the second conductive layer is formed by the same process as the circuit wiring layer.

5. The capacitance type input device according to claim 1,
wherein the circuit side insulating layer is formed in the same layer configuration as the sensor side insulating layer.

6. The capacitance type input device according to claim 1,
wherein a first driving electrode and a second driving electrode formed perpendicular to each other to be insulated from each other and the detection electrode opposite at a distance to the first driving electrode and the second driving electrode are disposed at the sensor portion, and the reference capacitor portion includes a first reference capacitor portion having a reference capacitance for capacitance between the first driving electrode and the detection electrode and a second reference capacitor portion having a reference capacitance for capacitance between the second driving electrode and the detection electrode.

7. The capacitance type input device according to claim 1,
wherein a condenser chip for fine adjustment of the reference capacitance is disposed at the reference capacitor portion.
